(19) United States
(12) Patent Application Publication
(10) Pub. No.: US 2026/0068430 A1
(43) Pub. Date: Mar. 5, 2026

(54) SCREEN PRINTING DEVICE AND SCREEN PRINTING METHOD USING THE SAME

(71) Applicant: Samsung Display Co., Ltd., Yongin-si (KR)

(72) Inventor: Dae Hong KIM, Yongin-si (KR)

(21) Appl. No.: 19/176,538

(22) Filed: Apr. 11, 2025

(30) Foreign Application Priority Data
Aug. 30, 2024 (KR) 10-2024-0117386

(51) Int. Cl. H10K 59/12; B41F 15/08; B41F 15/36; B41M 1/12; B41M 1/26; H10K 71/13

(52) U.S. Cl. CPC H10K 59/1201; B41F 15/0818; B41F 15/36; B41M 1/12; B41M 1/26; H10K 71/13

(57) ABSTRACT

A screen printing device includes a stage on which a display panel is disposed, a mask assembly disposed on the display panel, a coating member for applying a polymer paste onto the mask assembly, a pressing member for bringing the mask assembly into contact with the display panel, and a blocking member disposed at an edge of the mask assembly.

This application claims priority to Korean Patent Application No. 10-2024-0117386 filed on Aug. 30, 2024, and all the benefits accruing therefrom under 35 U.S.C. § 119, the content of which in its entirety is herein incorporated by reference.

### BACKGROUND

### 1. Field

The disclosure relates to a screen printing device and a screen printing method using the same.

### 2. Description of the Related Art

Display devices become more and more important as multimedia technology evolves. Accordingly, a variety of types of display devices such as organic light-emitting display (“OLED”) devices and liquid-crystal display (“LCD”) devices are currently used.

Display devices are for displaying images and include a display panel such as an organic light-emitting display panel and a liquid-crystal display panel. A protective layer is formed on the rear surface of a display panel, i.e., the surface opposite to the display surface that displays images of the display panel, to protect the display panel. The protective layer may be formed on the rear surface of the display panel by a screen printing process.

### SUMMARY

Features of the disclosure provide a screen printing device that may prevent a protective layer from being formed at an incorrect location on a display panel, during a screen printing process for forming the protective layer on the display panel, and a screen printing method.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a screen printing device includes a stage on which a display panel is disposed, a mask assembly disposed on the display panel, a coating member for applying a polymer paste onto the mask assembly, a pressing member for bringing the mask assembly into contact with the display panel, and a blocking member disposed at an edge of the mask assembly.

In an embodiment, the blocking member is extended from the edge of the mask assembly to an upper surface of the display panel, so that a space between the edge of the mask assembly and the upper surface of the display panel is closed.

In an embodiment, an upper end of the blocking member is flush with an upper surface of the mask assembly.

In an embodiment, the blocking member is provided as an air blower disposed at the edge of the mask assembly, wherein the air blower forms an air blocking layer by blowing air from the edge of the mask assembly toward the display panel, and wherein the air blocking layer closes a space between the edge of the mask assembly an the upper surface of the display panel.

In an embodiment, the blocking member is disposed higher than the mask assembly.

In an embodiment, the display panel is divided into a display area and a non-display area, and the mask assembly is disposed on the display area.

In an embodiment, the blocking member is disposed on the non-display area of the display panel.

In an embodiment, the coating member contacts an upper surface of the mask assembly and is movable in a direction in which the mask assembly is extended.

In an embodiment, the pressing member is movable in a thickness direction of the display panel, and presses the mask assembly toward the display panel.

In an embodiment, the mask assembly includes a mask portion covering an upper surface of the display panel, and a plurality of transmissive areas penetrating the mask portion, and wherein when the mask assembly contacts the display panel by the pressing member, the polymer paste passes through the plurality of transmissive areas and is applied onto the upper surface of the display panel.

In an embodiment of the disclosure, a screen printing method includes placing a display panel on a stage, disposing a mask assembly on the display panel, disposing a blocking member at an edge of the mask assembly, applying a polymer paste onto the mask assembly, and bringing the mask assembly into contact with the display panel.

In an embodiment, the display panel is divided into a display area and a non-display area, and wherein the disposing the mask assembly on the display panel includes disposing the mask assembly on the display area.

In an embodiment, the disposing the mask assembly on the display panel includes disposing the mask assembly so that the mask assembly is spaced apart from the display panel.

In an embodiment, the disposing the blocking member at the edge of the mask assembly includes disposing the blocking member on an upper surface of the display panel so that one side of the blocking member contacts the edge of the mask assembly.

In an embodiment, an upper end of the blocking member is flush with an upper surface of the mask assembly.

In an embodiment, the blocking member is provided as an air blower, and wherein the disposing the blocking member at the edge of the mask assembly includes forming an air blocking layer between the edge of the mask assembly and an upper surface of the display panel by disposing the air blower at the edge of the mask assembly and blowing air toward the display panel.

In an embodiment, the blocking member is disposed higher than the mask assembly.

In an embodiment, the disposing the blocking member at the edge of the mask assembly includes disposing the blocking member on the non-display area of the display panel.

In an embodiment, the applying the polymer paste onto the mask assembly includes applying the polymer paste onto an upper surface of the mask assembly by moving the coating member in a direction in which the mask assembly is extended, with a coating member in contact with the upper surface of the mask assembly.

In an embodiment, the bringing the mask assembly into contact with the display panel includes moving a pressing member in a thickness direction of the display panel above the mask assembly to press the mask assembly toward the display panel.

In an embodiment of the disclosure, an electronic device includes a display device manufactured by a screen printing device, the screen printing device includes a stage on which a display panel is disposed, a mask assembly disposed on the display panel, a coating member for applying a polymer paste onto the mask assembly, a pressing member for bringing the mask assembly into contact with the display panel, and a blocking member disposed at an edge of the mask assembly.

In an embodiment of the disclosure, by disposing a blocking member at an edge of a mask assembly, it is possible to prevent a polymer paste from overflowing out of the mask assembly during a screen printing process of forming a protective layer on a display panel, thereby preventing the protective layer from being formed at an incorrect location on the display panel.

The effects in the embodiments of the disclosure are not limited to those mentioned above and more various effects are included in the following description of the disclosure.

### BRIEF DESCRIPTION OF THE DRAWINGS

The above and other advantages and features of the disclosure will become more apparent by describing in detail embodiments thereof with reference to the attached drawings, in which:

FIG. 1 is a view schematically showing an embodiment of a screen printing device according to the disclosure.

FIG. 2 is a plan view of an embodiment of a display panel on which a protective layer is formed by the screen printing device according to the disclosure.

FIG. 3 is a cross-sectional view taken along line A-A′ of FIG. 2.

FIG. 4 is a cross-sectional view showing the display panel of FIG. 3.

FIG. 5 is a view schematically showing another embodiment of a screen printing device according to the disclosure.

FIG. 6 is a flowchart for illustrating an embodiment of a screen printing method according to the disclosure.

FIG. 7 is a view showing the placing a display panel on the stage in FIG. 6.

FIG. 8 is a view showing the disposing a mask assembly above the display panel in FIG. 6.

FIGS. 9 and 10 are views showing disposing a blocking member at an edge of the mask assembly in FIG. 6.

FIGS. 11 and 12 are views showing the applying a polymer paste onto the mask assembly in FIG. 6.

FIGS. 13 and 14 are views showing the bringing the mask assembly into contact with the display panel to form a protect layer on the display panel in FIG. 6.

FIG. 15 is a block diagram of an embodiment of an electronic device according to the disclosure.

FIG. 16 is a schematic diagram of an electronic device according to various embodiments of the disclosure.

### DETAILED DESCRIPTION

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The drawing figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments may be practiced individually or in combination.

Hereinafter, embodiments of the disclosure will be described in detail with reference to the accompanying drawings.

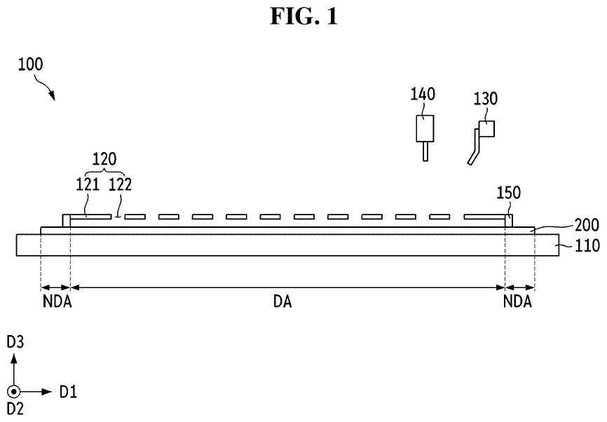

FIG. 1 is a view schematically showing an embodiment of a screen printing device according to the disclosure.

Referring to FIG. 1, a screen printing device 100 in an embodiment of the disclosure may include a stage 110, a mask assembly 120, a coating member 130, a pressing member 140, and a blocking member 150.

The stage 110 may provide a space for a display panel 200 to be disposed (e.g., seated). In some embodiments, the stage 110 may settle and fix the display panel. The stage 110 may be provided as a plate having a predetermined thickness. The shape of the stage 110 may be, but is not limited to, a quadrangular shape, e.g., rectangular shape when viewed from the top. The stage 10 may have a quadrangular shape, e.g., rectangular shape having longer sides in the first direction D1 and shorter sides in the second direction D2 when viewed from the top. The size of the stage 110 may be larger than the size of the display panel 200 when viewed from the top.

The display panel 200 may be disposed (e.g., seated) on the upper surface of the stage 110. Since a protective layer PL is formed on the rear surface of the display panel 200, that is, on the surface opposite to the display surface of the display panel 200, the display panel 200 may be disposed (e.g., seated) on the stage 110 so that the rear surface faces the upper surface of the stage 110. In some embodiments, the display panel 200 may be disposed (e.g., seated) on the stage 110 such that the display surface contacts the upper surface of the stage 110.

Before describing remaining (the other) elements of the screen printing device 100, the display panel 200 on which a protective layer is formed by the screen printing device 100 in the embodiment of the disclosure will be described.

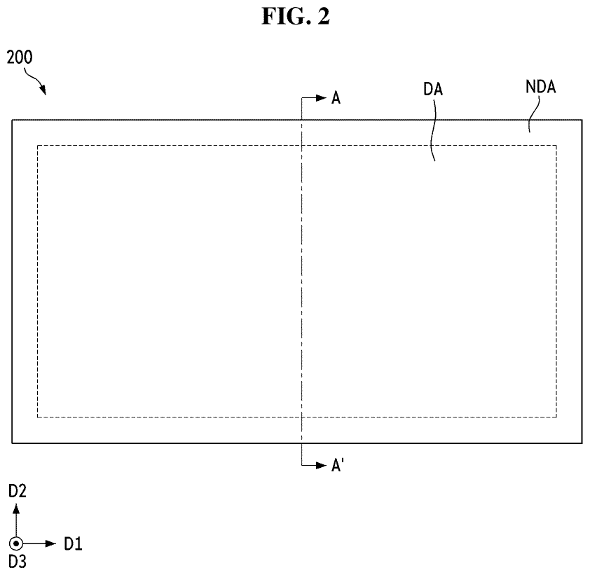

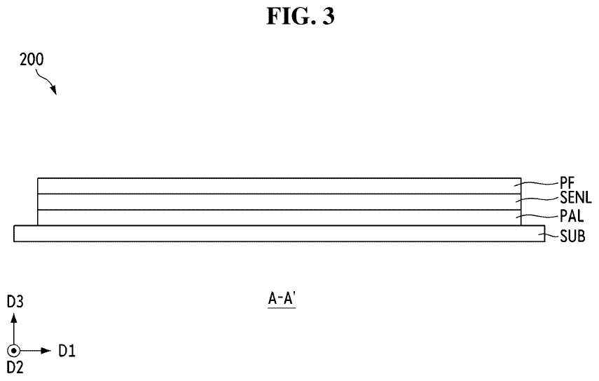

FIG. 2 is a plan view of an embodiment of a display panel on which a protective layer is formed by the screen printing device according to the disclosure. FIG. 3 is a cross-sectional view taken along line A-A′ of FIG. 2.

Referring to FIGS. 2 and 3, the display panel 200 may have a quadrangular shape, e.g., rectangular shape having longer sides in the first direction D1 and shorter sides in the second direction D2 when viewed from the top. In the display panel 200, the corners where the longer sides in the first direction D1 meet the shorter sides in the second direction D2 may be formed at a right angle or may be rounded with a predetermined curvature. The display panel 200 may have a quadrangular shape other than a rectangle, a polygonal shape other than a quadrangular shape, a circular shape, an oval shape, or an irregular shape when viewed from the top.

The display panel 200 may include a display area DA where emission areas are disposed to emit light, and a non-display area NDA around the display area DA. The non-display area NDA may surround the display area DA. A plurality of display pads may be disposed in the non-display area NDA at one edge of the display panel 200.

The display panel 200 may include a substrate SUB, a display unit PAL, a sensor unit SENL and a polarizing film PF.

The substrate SUB may include or consist of an insulating material such as glass, quartz and a polymer resin. The substrate SUB may be a rigid substrate or a flexible substrate that may be bent, folded, rolled, and so on.

The display unit PAL may be disposed on the substrate SUB. The display unit PAL may be a layer including a plurality of emission areas that emit light. The display unit PAL may include a buffer film, a thin-film transistor layer on which thin-film transistors are disposed, a light-emitting element layer that emits light, and an encapsulating layer for encapsulating the light-emitting element layer.

The sensor unit SENL may be disposed on the display unit PAL. The sensor unit SENL may include sensor electrodes and may sense whether there is a user's touch.

The polarizing film PF may be disposed on the sensor unit SENL. The polarizing film PF may prevent the deterioration of image visibility of the display panel 200 due to reflection of external light. The polarizing film may include a linear polarizer and a retardation film such as a λ/4 (quarter-wave) plate. The phase retardation film may be disposed on the sensor unit SENL, and the linear polarizer may be disposed on the phase retardation film.

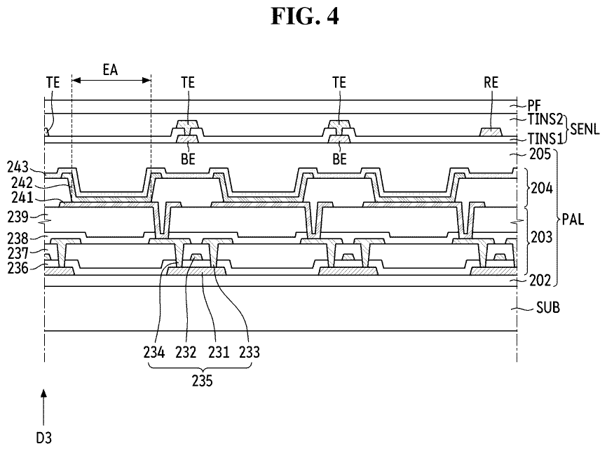

FIG. 4 is a cross-sectional view showing the display panel of FIG. 3.

Referring to FIG. 4, the display unit PAL may include a buffer film 202, a thin-film transistor layer 203, a light-emitting element layer 204, and an encapsulation layer 205.

The buffer film 202 may be formed on the substrate SUB. The buffer film 202 may be formed on the substrate SUB to protect the thin-film transistors 235 and the light-emitting elements from moisture permeating through the substrate SUB that is susceptible to moisture permeation. The buffer film 202 may include or consist of a plurality of inorganic layers stacked on one another alternately. In an embodiment, the buffer film 202 may be made up of multiple layers in which one or more inorganic layer of a silicon oxide layer (SiOx), a silicon nitride layer (SiNx) and SiON are stacked on one another alternately, for example. The buffer film 202 may be eliminated.

The thin-film transistor layer 203 is formed on the buffer film 202. The thin-film transistor layer 203 includes thin-film transistors 235, a gate insulator 236, an inter-dielectric layer 237, a protective film 238, and an organic film 239.

Each of the thin-film transistor 235 includes an active layer 231, a gate electrode 232, a source electrode 233, and a drain electrode 234. In FIG. 4, the thin-film transistors 235 are implemented as top-gate transistors in which the gate electrode 232 is disposed above the active layer 231. It is, however, to be understood that the disclosure is not limited thereto. That is to say, the thin-film transistors 235 may be implemented as bottom-gate transistors in which the gate electrode 232 is disposed below the active layer 231, or as double-gate transistors in which the gate electrodes 232 are disposed above and below the active layer 231.

The active layer 231 is formed on the buffer film 202. The active layer 231 may include or consist of a silicon-based semiconductor material or an oxide-based semiconductor material. In an embodiment, the active layer 231 may include or consist of polycrystalline silicon, amorphous silicon, or an oxide semiconductor, for example. A light-blocking layer for blocking external light incident on the active layer 231 may be formed between the buffer film 202 and the active layer 231.

The gate insulator 236 may be formed on the active layer 231. The gate insulator 236 may include or consist of an inorganic layer, e.g., a silicon oxide layer (SiOx), a silicon nitride layer (SiNx), or a multilayer thereof.

The gate electrodes 232 may be formed on the gate insulator (also referred to as an insulating layer) 236. The gate electrodes 232 and the gate lines may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The inter-dielectric layer 237 may be formed over the gate electrodes 232 and the gate lines. The inter-dielectric layer 237 may include or consist of an inorganic layer, e.g., a silicon oxide layer (SiOx), a silicon nitride layer (SiNx), or a multilayer thereof.

The source electrodes 233 and the drain electrodes 234 may be formed on the inter-dielectric layer 237. Each of the source electrodes 233 and the drain electrodes 234 may be connected to the active layer 231 through a contact hole penetrating through the gate insulating layer 236 and the inter-dielectric layer 237. The source electrode 233 and the drain electrode 234 may be made up of a single layer or multiple layers of one of molybdenum (Mo), aluminum (AI), chromium (Cr), gold (Au), titanium (Ti), nickel (Ni), neodymium (Nd) and copper (Cu) or any alloys thereof.

The protective film 238 may be formed on the source electrode 233 and the drain electrode 234 in order to insulate the thin-film transistors 235. The protective layer 238 may include or consist of an inorganic layer, e.g., a silicon oxide layer (SiOx), a silicon nitride layer (SiNx), or a multilayer thereof.

The organic film 239 may be formed on the protective film 238 to provide a flat surface over the thin-film transistors 235 having difference levels. The organic film 239 may be implemented as an organic layer such as an acryl resin, an epoxy resin, a phenolic resin, a polyamide resin and a polyimide resin.

The light-emitting element layer 204 is formed above the thin-film transistor layer 203. The light-emitting element layer 204 includes the light-emitting elements and a bank.

The light-emitting elements and the bank are formed on the organic film 239. An organic light-emitting device including an anode electrode 241, emissive layers 242 and a cathode electrode 243 is employed in an embodiment of the light-emitting elements.

The anode electrode 241 may be formed on the organic film 239. The anode electrode 241 may be connected to the source electrode 233 of the thin-film transistor 235 via a contact hole penetrating through the protective film 238 and the organic film 239.

The bank may be formed to cover the edge of the anode electrode 241 on the organic film 239 to define the emission areas EA of the pixels. That is to say, the bank may define the emission areas EA of the pixels. In each of the pixels, the anode electrode 241, the emissive layer 242 and the cathode electrode 243 are sequentially stacked on one another so that holes from the anode electrode 241 and electrons from the cathode electrode 243 combine in the emissive layer 242 to emit light.

The emissive layers 242 are formed on the anode electrode 241 and the bank. The emissive layers 242 may be organic emissive layers. The emissive layers 242 may emit one of red light, green light, and blue light. In an alternative embodiment, the emissive layer 242 may be a white emissive layer that emits white light. In such case, the red emissive layer, the green emissive layer and the blue emissive layer may be stacked on one another or may be formed commonly across the pixels as a common layer. In such case, the display panel 200 may further include additional color filters for representing red, green and blue colors.

The emissive layer 242 may include a hole transporting layer, a light-emitting layer, and an electron transporting layer. In addition, the emissive layer 242 may be formed in a tandem structure of two or more stacks, in which case a charge generating layer may be formed between the stacks.

The cathode electrode 243 is formed on the emissive layer 242. The cathode electrode 243 may be formed to cover the emissive layer 242. The cathode electrode 243 may be a common layer formed across the pixels.

When the light-emitting element layer 204 is of a top-emission type in which light exits toward the upper side, the anode electrode 241 may include or consist of a metal material having a relatively high reflectivity such as a stack structure of aluminum and titanium (Ti/Al/Ti), a stack structure of aluminum and indium-tin-oxide (“ITO”) (“ITO/Al/ITO”), an APC alloy and a stack structure of APC alloy and ITO (“ITO/APC/ITO”). The APC alloy is an alloy of silver (Ag), palladium (Pd) and copper (Cu). The cathode electrode 243 may include or consist of a transparent conductive material (“TCP”) such as ITO and IZO that may transmit light, or a semi-transmissive conductive material such as magnesium (Mg), silver (Ag) and an alloy of magnesium (Mg) and silver (Ag). When the cathode electrode 243 includes or consists of a semi-transmissive conductive material, the light extraction efficiency may be increased by microcavities.

When the light-emitting element layer 204 is of a bottom-emission type in which light exits toward the lower side, the anode electrode 241 may include or consist of a transparent conductive material (“TCP”) such as ITO and indium zinc oxide (“IZO”) that may transmit light, or a semi-transmissive conductive material such as magnesium (Mg), silver (Ag) and an alloy of magnesium (Mg) and silver (Ag). The cathode electrode 243 may include or consist of a metal material having a relatively high reflectivity such as a stack structure of aluminum and titanium (Ti/Al/Ti), a stack structure of ITO/Al/ITO, an APC alloy and a stack structure of ITO/APC/ITO. When the anode electrode 241 includes or consists of a semi-transmissive conductive material, the light extraction efficiency may be increased by microcavities.

The encapsulation layer 205 is formed on the light-emitting element layer 204. The encapsulation layer 205 serves to prevent permeation of oxygen or moisture into the emissive layers 242 and the cathode electrode 243. To this end, the encapsulation layer 205 may include at least one inorganic film. The inorganic layer may include or consist of silicon nitride, aluminum nitride, zirconium nitride, titanium nitride, hafnium nitride, tantalum nitride, silicon oxide, aluminum oxide, or titanium oxide. Further, the encapsulation layer 205 may further include at least one organic film. The organic film may have a sufficient thickness to prevent particles from permeating into the encapsulation layer 205 and entering the emissive layer 242 and the cathode electrode 243. The organic layer may include one of epoxy, acrylate and urethane acrylate.

The sensor unit SENL may be formed on the encapsulation layer 205. When the sensor unit SENL is formed directly on the encapsulation layer 205, the thickness of the display device 10 may be reduced, compared with a display device in which a separate touch panel is attached on the encapsulation layer.

The sensor unit SENL may include sensor electrodes for sensing a user's touch by capacitive sensing, and touch lines for connecting the pads with the sensor electrodes. In an embodiment, the sensor unit SENL may sense a user's touch by self-capacitance sensing or mutual capacitance sensing, for example. In the example shown in FIG. 4, the sensor unit SENL is made up of two layers including driving electrodes TE, sensing electrodes RE and bridges BE connecting between the driving electrodes TE for mutual capacitance sensing.

The bridges BE may be formed on the encapsulation layer 205. The bridges BE may be made up of, but is not limited to, a stack structure of aluminum and titanium (Ti/Al/Ti), a stack structure of ITO/AI/ITO, an APC alloy and a stack structure of ITO/APC/ITO. In an embodiment, the bridges BE may be made up of a single layer of molybdenum (Mo), titanium (Ti), copper (Cu), aluminum (Al) or ITO, for example.

A first sensing insulating film TINS1 is formed over the bridges BE. The first sensing insulating film TINS1 may include or consist of an inorganic film, e.g., a silicon nitride layer, a silicon oxynitride layer, a silicon oxide layer, a titanium oxide layer, or an aluminum oxide layer.

The driving electrodes TE and the sensing electrodes RE may be formed on the first sensing insulating film TINS1. The driving electrode TE and the sensing electrode RE may be formed as, but is not limited to, a stack structure of aluminum and titanium (Ti/Al/Ti), a stack structure of ITO/Al/ITO, an APC alloy and a stack structure of ITO/APC/ITO. In an embodiment, the driving electrodes TE and the sensing electrodes RE may be made up of a single layer of molybdenum (Mo), titanium (Ti), copper (Cu), aluminum (AI) or ITO, for example.

Contact holes may be formed in the first sensing insulating film TINS1 which penetrate the first sensing insulating film TINS1 to expose the bridges BE. The driving electrodes TE may be connected to the bridges BE through the contact holes.

A second sensing insulating film TINS2 is formed over the driving electrodes TE and the sensing electrodes RE. The second sensing insulating film TINS2 may provide a flat surface over the driving electrodes TE, the sensing electrodes RE and the bridges BE which have different heights. The second sensing insulating film TINS2 may include or consist of an organic layer such as an acryl resin, an epoxy resin, a phenolic resin, a polyamide resin and a polyimide resin.

The bridges BE connecting between the neighboring (adjacent) driving electrodes TE may be disposed on the encapsulation layer 205, and the driving electrodes TE and the sensing electrodes RE may be disposed on the first sensing insulating film TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The polarizing film PF may be disposed on the second sensing insulating film TINS2 and may prevent the deterioration of image visibility of the display panel 200 due to reflection of external light.

Referring back to FIG. 1, the mask assembly 120 may define an area where a polymer paste P is applied on the display panel. The mask assembly 120 may be disposed on the display panel 200. The mask assembly 120 may be disposed on the display area DA of the display panel 200. The mask assembly 120 may include a mask portion 121, and a transmissive area 122 may be defined in the mask assembly 120.

The mask portion 121 may cover some regions of the display panel 200 to prevent the polymer paste P from being applied onto the covered regions. The size of the mask portion 121 may be equal to the size of the display area DA of the display panel 200 when viewed from the top.

The transmissive area 122 may be open regions defined between the mask portions 121 that expose some regions of the display panel 200. In some embodiments, the transmissive area 122 may penetrate the mask portion 121 in the thickness direction. The polymer paste P may be applied to the exposed regions of the display panel 200 exposed by the transmissive area 122. Before the mask assembly 120 is pressed by the pressing member 140, it may be placed above the display panel 200 such that it is spaced apart from the display panel 200, and may contact the display panel 200 by being pressed by the pressing member 140. In the process of bringing the mask assembly 120 into contact with the display panel 200, the polymer paste P may pass through the transmissive area 122 and applied to the rear surface of the display panel 200. There may be a plurality of transmissive areas 122 spaced apart from one another throughout the entirety of the mask portion 121.

The coating member 130 may apply the polymer paste P to the mask assembly 120. The coating member 130 may be disposed above the mask assembly 120, and may be movable in a third direction D3, which is the thickness direction of the mask assembly 120, and may be movable in the first direction D1 and the second direction D2, in which the mask assembly 120 is extended.

Once the polymer paste P is disposed (e.g., seated) on the upper surface of the mask assembly 120, the coating member 130 may be moved in the third direction D3 so that the lower end of the coating member 130 may contact the upper surface of the mask assembly 120. After the lower end of the coating member 130 contacts the upper surface of the mask assembly 120, the coating member 130 may be moved in the first direction D1 and the second direction D2 to evenly apply the polymer paste P onto the upper surface of the mask assembly 120. In the process of applying the polymer paste P onto the upper surface of the mask assembly 120, the polymer paste P may be introduced into the transmissive area 122 of the mask assembly 120.

The pressing member 140 may bring the mask assembly 120 into contact with the display panel 200. In some embodiments, the pressing member 140 may press the mask assembly 120 to bring the lower surface of the mask assembly 120 into contact with the upper surface of the display panel 200. The pressing member 140 may be disposed above the mask assembly 120, and may be movable in a third direction D3, which is the thickness direction of the mask assembly 120, and may be movable in the first direction D1 and the second direction D2, in which the mask assembly 120 is extended.

The pressing member 140 may be moved in the third direction D3 so that the lower end of the pressing member 140 may pressurize the mask assembly 120. As the pressing member 140 presses the mask assembly 120, the mask assembly 120 may contact the display panel 200. With a part of the mask assembly 120 pressed by the pressing member 140 into contact with the display panel 200, the pressing member 140 may be moved in the first direction D1 and the second direction D2 so that the entirety of the mask assembly 120 may contact the display panel 200. In the process of bringing the mask assembly 120 into contact with the display panel 200, the polymer paste P introduced into the transmissive area 122 may be applied to the display panel 200.

The blocking member 150 may be disposed at an edge of the mask assembly 120 to close the space between the edge of the mask assembly 120 and the upper surface of the display panel 200. The blocking member 150 may be extended from the edge of the mask assembly 120 to the upper surface of the display panel 200. There may be a plurality of blocking members 150, which may be arranged on the both edges of the mask assembly 120 in the first direction D1 and on the both edges of the mask assembly 120 in the second direction D2. The upper end of the blocking member 150 may be flush with the upper surface of the mask assembly 120. Since one side of the blocking member 150 contacts the edge of the mask assembly 120, the blocking member 150 may be disposed on the non-display area NDA of the display panel 200.

Since the blocking member 150 is disposed to close the space between the edge of the mask assembly 120 and the upper surface of the display panel 200, it is possible to prevent the polymer paste P from overflowing out of the mask assembly 120 when the mask assembly 120 is pressed and contacts the upper surface of the display panel 200. In some embodiments, it is possible to prevent the polymer paste P from being applied on the non-display area NDA of the display panel 200 by the blocking member 150.

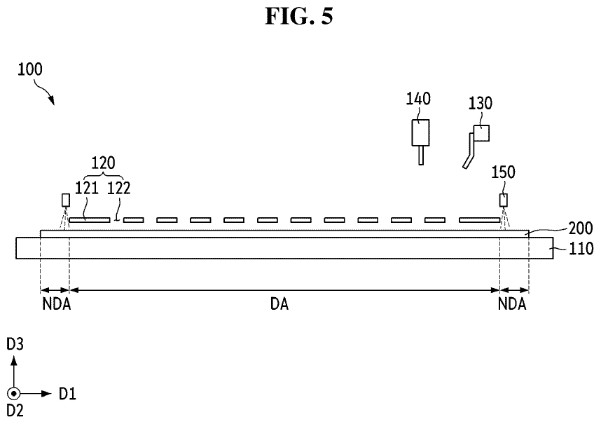

FIG. 5 is a view schematically showing another embodiment of a screen printing device according to the disclosure.

Referring to FIG. 5, the blocking member 150 may be disposed at an edge of the mask assembly 120 to close the space between the edge of the mask assembly 120 and the upper surface of the display panel 200. The blocking member 150 may be provided as an air blower. As the blocking member 150 is provided as an air blower, the blocking member 150 may be placed above the edge of the mask assembly 120 and may form an air blocking layer by blowing air from above the edge of the mask assembly 120 toward the display panel 200. The air blocking layer may close the space between the edge of the mask assembly 120 and the upper surface of the display panel 200. There may be a plurality of blocking members 150 and may be arranged on the both edges of the mask assembly 120 in the first direction D1 and on the both edges of the mask assembly 120 in the second direction D2. The blocking member 150 may be disposed on the non-display area NDA of the display panel 200.

Since the air blocking layer formed by the air blown from the blocking member 150 is disposed to close the space between the edge of the mask assembly 120 and the upper surface of the display panel 200, it is possible to prevent the polymer paste P from overflowing out of the mask assembly 120 when the mask assembly 120 is pressed and contacts the upper surface of the display panel 200. In some embodiments, it is possible to prevent the polymer paste P from being applied on the non-display area NDA of the display panel 200 by the blocking member 150.

Hereinafter, a screen printing method in an embodiment of the disclosure will be described with reference to the accompanying drawings.

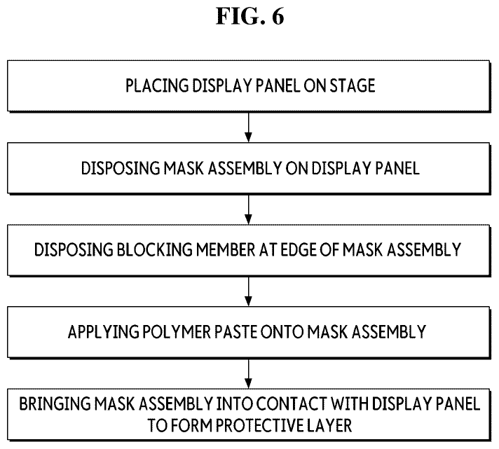

FIG. 6 is a flowchart for illustrating an embodiment of a screen printing method according to the disclosure.

Referring to FIG. 6, a screen printing method in an embodiment of the disclosure may include placing a display panel 200 on a stage 110, disposing a mask assembly 120 on the display panel 200, disposing a blocking member 150 at an edge of the mask assembly 120, applying a polymer paste P onto the mask assembly 120, and bringing the mask assembly 120 into contact with the display panel 200.

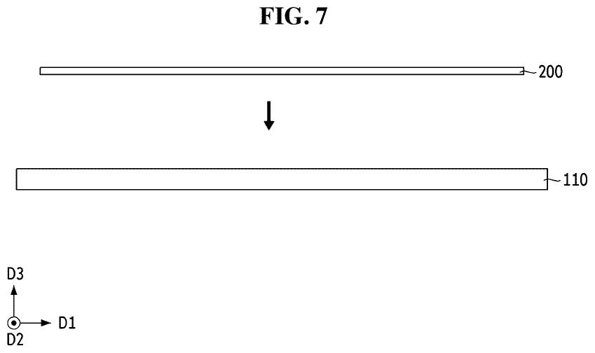

FIG. 7 is a view showing the placing a display panel on the stage in FIG. 6.

Referring to FIG. 7, the placing the display panel 200 on the stage 110 may include placing the display panel 200 on the stage 110 such that the lower surface of the display panel 200, that is, the display surface of the display panel 200, contacts the upper surface of the stage 110. The size of the stage 110 may be larger than the size of the display panel 200 when viewed from the top and the display panel 200 may be placed at the center of the stage 110.

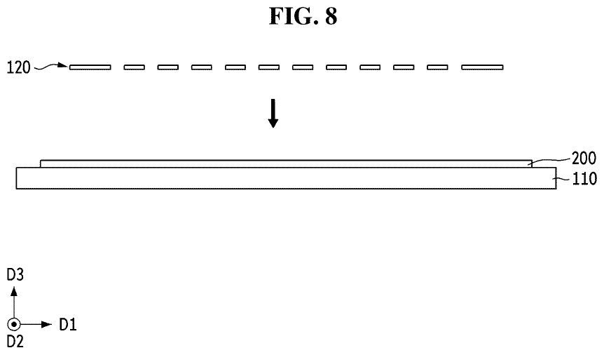

FIG. 8 is a view showing the disposing a mask assembly above the display panel in FIG. 6.

Referring to FIG. 8, the disposing the mask assembly 120 above the display panel 200 may include disposing the mask assembly 120 above the display area DA of the display panel 200. In the disposing the mask assembly 120 above the display panel 200, the mask assembly 120 may be spaced apart from the display panel 200.

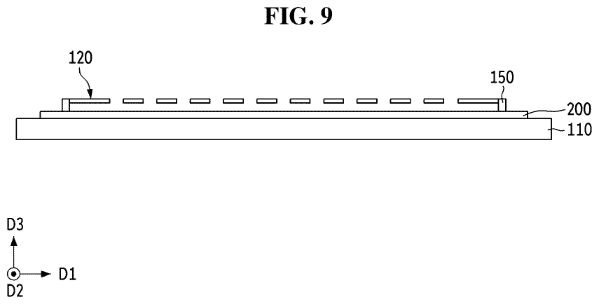

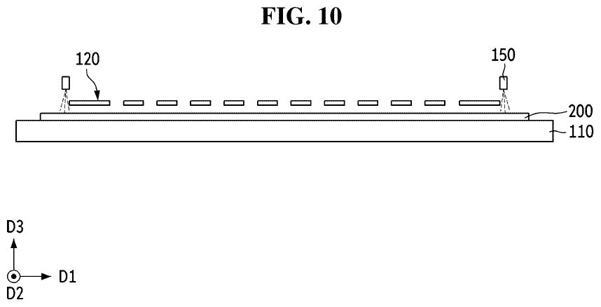

FIGS. 9 and 10 are views showing disposing a blocking member at an edge of the mask assembly in FIG. 6.

Referring to FIG. 9, the disposing the blocking member 150 at the edge of the mask assembly 120 may include disposing the blocking member 150 on the upper surface of the display panel 200 such that one side of the blocking member 150 contacts the edge of the mask assembly 120. The blocking member 150 may be extended from the edge of the mask assembly 120 to the upper surface of the display panel 200. In the disposing the blocking member 150 at the edge of the mask assembly 120, there may be a plurality of blocking members 150, which may be arranged on the both edges of the mask assembly 120 in the first direction D1 and on the both edges of the mask assembly 120 in the second direction D2. The upper end of the blocking member 150 may be flush with the upper surface of the mask assembly 120. The blocking member 150 may be disposed on the non-display area NDA of the display panel 200. As described above, it is possible to close the space between the edge of the mask assembly 120 and the upper surface of the display panel 200 by the blocking member 150 disposed at the edge of the mask assembly 120.

Referring to FIG. 10, the blocking member 150 may be provided as an air blower, and the disposing the blocking member 150 at the edge of the mask assembly 120 may include disposing the blocking member 150 provided as the air blower on the edge of the mask assembly 120 and blowing air toward the display panel 200 to form an air blocking layer. The air blocking layer may close the space between the edge of the mask assembly 120 and the upper surface of the display panel 200. In the disposing the blocking member 150 at the edge of the mask assembly 120, there may be a plurality of blocking members 150, which may be arranged on the both edges of the mask assembly 120 in the first direction D1 and on the both edges of the mask assembly 120 in the second direction D2. The blocking member 150 may be disposed on the non-display area NDA of the display panel 200.

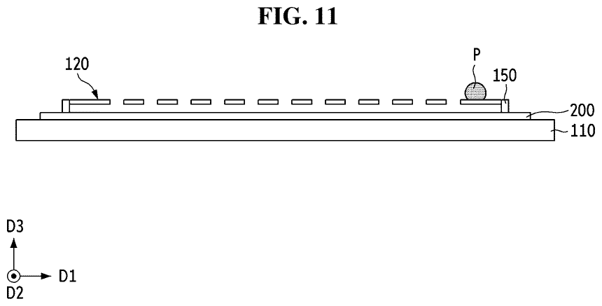

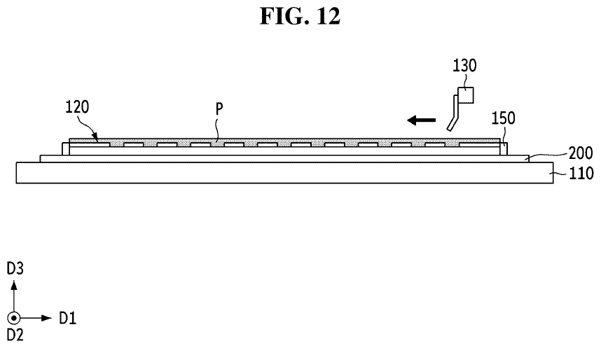

FIGS. 11 and 12 are views showing the applying a polymer paste onto the mask assembly in FIG. 6.

Referring to FIG. 11, after the blocking member 150 is disposed at the edge of the mask assembly 120, a lump of polymer paste P may be disposed (e.g., seated) on the upper surface of the mask assembly 120.

Referring to FIG. 12, the applying the polymer paste P onto the mask assembly 120 may include applying the polymer paste P onto the upper surface of the mask assembly 120 by moving the coating member 130 in a direction in which the mask assembly 120 is extended with the coating member 130 in contact with the upper surface of the mask assembly 120.

Once the lump of the polymer paste P is disposed (e.g., seated) on the upper surface of the mask assembly 120, the coating member 130 may be moved in the third direction D3 so that the lower end of the coating member 130 may contact the upper surface of the mask assembly 120. After the lower end of the coating member 130 contacts the upper surface of the mask assembly 120, the coating member 130 may be moved in the first direction D1 and the second direction D2 to evenly apply the polymer paste P onto the upper surface of the mask assembly 120. In the process of applying the polymer paste P onto the upper surface of the mask assembly 120, the polymer paste P may be introduced into the transmissive area 122 of the mask assembly 120.

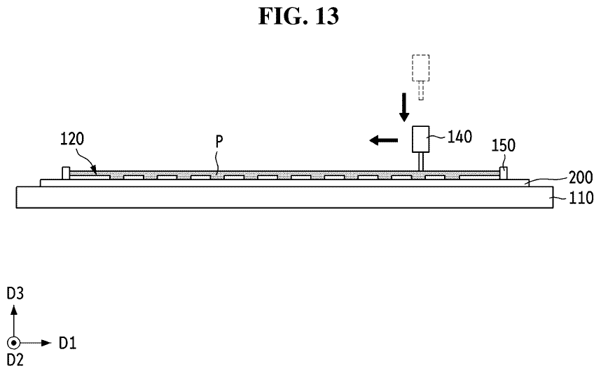

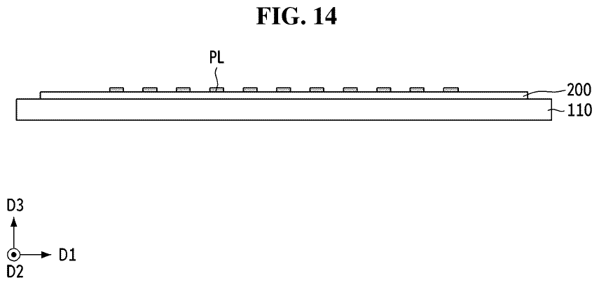

FIGS. 13 and 14 are views showing the bringing the mask assembly into contact with the display panel to form a protect layer on the display panel in FIG. 6.

Referring to FIG. 13, the bringing the mask assembly 120 into contact with the display panel 200 may include moving a pressing member 140 in the thickness direction of the display panel 200 from above the mask assembly 120 to press the mask assembly 120 toward the display panel 200.

The pressing member 140 may be disposed above the mask assembly 120, and may be movable in a third direction D3, which is the thickness direction of the mask assembly 120, and may be movable in the first direction D1 and the second direction D2, in which the mask assembly 120 is extended.

The pressing member 140 may be moved in the third direction D3 so that the lower end of the pressing member 140 may pressurize the mask assembly 120. As the pressing member 140 presses the mask assembly 120, the mask assembly 120 may contact the display panel 200. With a part of the mask assembly 120 pressed by the pressing member 140 into contact with the display panel 200, the pressing member 140 may be moved in the first direction D1 and the second direction D2 so that the entirety of the mask assembly 120 may contact the display panel 200. In the process of bringing the mask assembly 120 into contact with the display panel 200, the polymer paste P introduced into the transmissive area 122 may be applied to the display panel 200.

Since the blocking member 150 closes the space between the edge of the mask assembly 120 and the upper surface of the display panel 200 during the process of bringing the mask assembly 120 into contact with the display panel 200, it is possible to prevent the polymer paste P from overflowing out of the mask assembly 120 when the mask assembly 120 is pressed and contacts the upper surface of the display panel 200. In some embodiments, it is possible to prevent the polymer paste P from being applied on the non-display area NDA of the display panel 200 by the blocking member 150.

Referring to FIG. 14, after the polymer paste P is applied onto the display panel 200, the mask assembly 120 and the blocking member 150 may be separated from the display panel 200. After the mask assembly 120 and the blocking member 150 have been separated from the display panel 200, a heat treatment process or a process of drying the display panel 200 for a predetermined period of time may be performed, to form a protective layer PL on the rear surface of the display panel 200.

The display device in an embodiment of the disclosure may be applied to various electronic devices. The electronic device according to the an embodiment of the disclosure includes the display device described above, and may further include modules or devices having additional functions in addition to the display device.

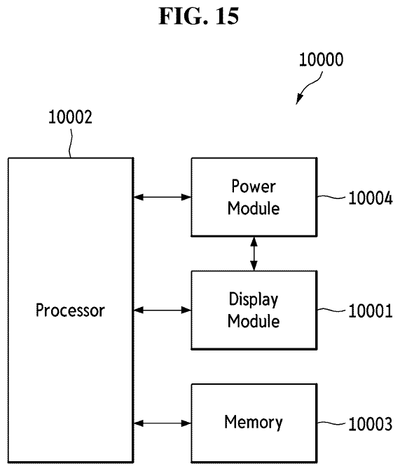

FIG. 15 is a block diagram of an embodiment of an electronic device according to the disclosure.

Referring to FIG. 15, the electronic device 10000 in an embodiment of the disclosure may include a display module 10001, a processor 10002, a memory 10003, and a power module 10004.

The processor 10002 may include at least one of a central processing unit (“CPU”), an application processor (“AP”), a graphic processing unit (“GPU”), a communication processor (“CP”), an image signal processor (“ISP”), and a controller.

The memory 10003 may store data information desired for the operation of the processor 10002 or the display module 10001. When the processor 10002 executes an application stored in the memory 10003, an image data signal and/or an input control signal is transmitted to the display module 10001, and the display module 10001 may process the received signal and output image information through a display screen.

The power module 10004 may include a power supply module such as, for example a power adapter or a battery, and a power conversion module that converts the power supplied by the power supply module to generate power desired for the operation of the electronic device 10000.

At least one of the components of the electronic device 10000 according to the an embodiment of the disclosure may be included in the display device in the embodiments of the disclosure. In addition, some modules of the individual modules functionally included in one module may be included in the display device, and other modules may be provided separately from the display device. In an embodiment, the display device may include the display module 10001, and the processor 10002, the memory 10003, and the power module 10004 may be provided in the form of other devices within the electronic device 10000 other than the display device, for example.

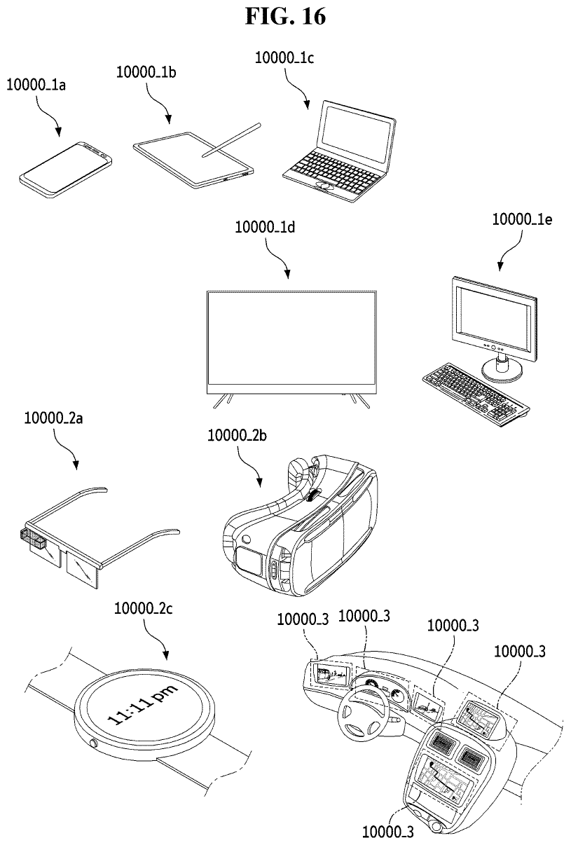

FIG. 16 is a schematic diagram of an electronic device according to various embodiments of the disclosure.

Referring to FIG. 16, various electronic devices to which display devices in embodiments of the disclosure are applied may include not only image display electronic devices such as a smart phone 10000_1a, a tablet personal computer (“PC”) 10000_1b, a laptop 10000_1c, a television (“TV”) 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a center information display (“CID”) and a room mirror display arranged on a dashboard, center fascia, and dashboard of an automobile.

It should be understood, however, that the advantages and features of embodiments of the disclosure are not restricted to the one set forth herein. The above and other features of the disclosure will become more apparent to one of ordinary skill in the art to which the disclosure pertains by referencing the claims, with equivalents thereof to be included therein.

What is claimed is:

1. A screen printing device comprising:
a stage on which a display panel is disposed;
a mask assembly disposed on the display panel;
a coating member which applies a polymer paste onto the mask assembly;
a pressing member which brings the mask assembly into contact with the display panel; and
a blocking member disposed at an edge of the mask assembly.

2. The screen printing device of claim 1, wherein the blocking member is extended from the edge of the mask assembly to an upper surface of the display panel, so that a space between the edge of the mask assembly and the upper surface of the display panel is closed.

3. The screen printing device of claim 2, wherein an upper end of the blocking member is flush with an upper surface of the mask assembly.

4. The screen printing device of claim 1, wherein the blocking member is provided as an air blower disposed at the edge of the mask assembly,
wherein the air blower forms an air blocking layer by blowing air from the edge of the mask assembly toward the display panel, and
wherein the air blocking layer closes a space between the edge of the mask assembly and an upper surface of the display panel.

5. The screen printing device of claim 4, wherein the blocking member is disposed higher than the mask assembly.

6. The screen printing device of claim 1, wherein the display panel is divided into a display area and a non-display area, and the mask assembly is disposed on the display area.

7. The screen printing device of claim 6, wherein the blocking member is disposed on the non-display area of the display panel.

8. The screen printing device of claim 1, wherein the coating member contacts an upper surface of the mask assembly and is movable in a direction in which the mask assembly is extended.

9. The screen printing device of claim 1, wherein the pressing member is movable in a thickness direction of the display panel, and presses the mask assembly toward the display panel.

10. The screen printing device of claim 1, wherein the mask assembly comprises:
a mask portion covering an upper surface of the display panel; and
a plurality of transmissive areas penetrating the mask portion, and
wherein when the mask assembly contacts the display panel by the pressing member, the polymer paste passes through the plurality of transmissive areas and is applied onto the upper surface of the display panel.

11. A screen printing method comprising:
placing a display panel on a stage;
disposing a mask assembly on the display panel;
disposing a blocking member at an edge of the mask assembly;
applying a polymer paste onto the mask assembly; and
bringing the mask assembly into contact with the display panel.

12. The screen printing method of claim 11, wherein the display panel is divided into a display area and a non-display area, and wherein the disposing the mask assembly on the display panel comprises: disposing the mask assembly on the display area.

13. The screen printing method of claim 12, wherein the disposing the mask assembly on the display panel comprises: disposing the mask assembly so that the mask assembly is spaced apart from the display panel.

14. The screen printing method of claim 11, wherein the disposing the blocking member at the edge of the mask assembly comprises: disposing the blocking member on an upper surface of the display panel so that one side of the blocking member contacts the edge of the mask assembly.

15. The screen printing method of claim 14, wherein an upper end of the blocking member is flush with an upper surface of the mask assembly.

16. The screen printing method of claim 11, wherein the blocking member is provided as an air blower, and
wherein the disposing the blocking member at the edge of the mask assembly comprises:
forming an air blocking layer between the edge of the mask assembly and an upper surface of the display panel by disposing the air blower at the edge of the mask assembly and blowing air toward the display panel.

17. The screen printing method of claim 16, wherein the blocking member is disposed higher than the mask assembly.

18. The screen printing method of claim 12, wherein the disposing the blocking member at the edge of the mask assembly comprises: disposing the blocking member on the non-display area of the display panel.

19. The screen printing method of claim 11, wherein the applying the polymer paste onto the mask assembly comprises: applying the polymer paste onto an upper surface of the mask assembly by moving a coating member in a direction in which the mask assembly is extended, with the coating member in contact with the upper surface of the mask assembly,
wherein the bringing the mask assembly into contact with the display panel comprises: moving a pressing member in a thickness direction of the display panel above the mask assembly to press the mask assembly toward the display panel.

20. An electronic device comprising:
a display device manufactured by a screen printing device, the screen printing device comprising:
a stage on which a display panel is disposed;
a mask assembly disposed on the display panel;
a coating member which applies a polymer paste onto the mask assembly;
a pressing member which brings the mask assembly into contact with the display panel; and
a blocking member disposed at an edge of the mask assembly.
